(19) United States
(12) Patent Application Publication
(10) Pub. No.: US 2009/0090930 A1
(43) Pub. Date: Apr. 9, 2009

(54) EPITAXIAL SUBSTRATE AND MANUFACTURING METHOD THEREOF AND MANUFACTURING METHOD OF LIGHT EMITTING DIODE APPARATUS

(76) Inventors: Shih-Peng Chen, Taoyuan Hsien (TW); Ching-Chuan Shiue, Taoyuan Hsien (TW); Chao-Min Chen, Taoyuan Hsien (TW); Cheng-Huang Kuo, Taoyuan Hsien (TW); Huang-Kun Chen, Taoyuan Hsien (TW)

Correspondence Address: Muncy, Geissler, Olds & Lowe, PLLC, P.O. BOX 1364, FAIRFAX, VA, 22038-1364, US

(21) Appl. No.: 12/198,331

(22) Filed: Aug. 26, 2008

(30) Foreign Application Priority Data
Oct. 5, 2007 (TW) 096137372

(51) Int. Cl. H01L 21/20; H01L 33/00

(52) U.S. Cl. 257/103; 438/478; 257/E33.025; 257/E21.09

(57) ABSTRACT

A manufacturing method of an epitaxial substrate includes the steps of: forming a sacrificial layer, which has a first micro/nano structure, on a substrate; and forming a buffer layer on the sacrificial layer. The sacrificial layer comprises a plurality of micro/nano particles, and the first micro/nano structure is formed after the plurality of micro/nano particles are removed. An epitaxial substrate and a manufacturing method of a light emitting diode (LED) apparatus are also disclosed.

### CROSS REFERENCE TO RELATED APPLICATIONS

This Non-provisional application claims priority under 35 U.S.C. §119(a) on Patent Application No(s). 096137372 filed in Taiwan, Republic of China on Oct. 5, 2007, the entire contents of which are hereby incorporated by reference.

### BACKGROUND OF THE INVENTION

1. Field of Invention

The invention relates to an epitaxial substrate and a manufacturing method thereof and, in particular, to a manufacturing method of a light emitting diode apparatus.

2. Related Art

A light emitting diode (LED) apparatus is a light emitting element made of semiconductor material. Since the LED apparatus advantageously has small size, low power consumption, no radiation, no mercury, long lifetime, high response speed and high reliability, the application range thereof covers the fields of the information electronic product, the communication electronic product, the consumer electronic product, the vehicle product, the illumination product and the traffic sign with the advancing technology.

Generally speaking, the LED must have an epitaxy multilayer grown on an epitaxial substrate, wherein an N-type epitaxial layer, an active layer and a P-type epitaxial layer are grown on the epitaxial substrate in sequence. In order to decrease the number of defects generated when the N-type epitaxial layer is directly growing on the flat epitaxial substrate, however, an epitaxial substrate having periodic holes is manufactured to prevent the defects from being formed.

FIGS. 1A to 1G show manufacturing processes of a LED apparatus 1.

As shown in FIG. 1A, the LED apparatus 1 is composed of a substrate 11, a buffer layer 12 and a mask layer 13. The buffer layer 12 is disposed between the substrate 11 and the mask layer 13.

As shown in FIG. 1B, the mask layer 13 is formed with a plurality of hollow portions H1 by anode aluminum oxide processing or etching in the prior art.

As shown in FIG. 1C, the buffer layer 12 is etched with the mask layer 13 serving as an etching mask so that the buffer layer 12 has hollow portions H2 corresponding to the hollow portions H1. In addition, the mask layer 13 is removed after the buffer layer 12 is etched.

As shown in FIG. 1D, an epitaxy multilayer 14 is formed on the buffer layer 12 and the hollow portions H2. The epitaxy multilayer 14 includes an N-type epitaxial layer 141, an active layer 142 and a P-type epitaxial layer 143. An N-type epitaxial layer 141 is formed on the buffer layer 12 and in the hollow portions H2. Next, the active layer 142 is formed on the N-type epitaxial layer 141, and then the P-type epitaxial layer 143 is formed on the active layer 142.

Referring to FIG. 1E, a thermoconductive adhesive layer 16 is formed on a thermoconductive substrate 15. Then, as shown in FIG. 1F, the thermoconductive adhesive layer 16 and the P-type epitaxial layer 143 are combined together. Finally, as shown in FIG. 1G, the LED apparatus 1 is turned over and the substrate 11 is removed by the laser lift-off technology.

In the conventional semiconductor manufacturing technology, however, complicated manufacturing steps have to be performed to form the nano-level hollow portions H1 by etching or electron beam exposure. Thus, the production yield is decreased. In addition, the apparatus cost for the laser lift-off technology is also very high. Therefore, it is an important subject to provide an epitaxial substrate, a manufacturing method of the epitaxial substrate and a manufacturing method of a LED apparatus capable of simplifying semiconductor manufacturing steps.

### SUMMARY OF THE INVENTION

The present invention is to provide an epitaxial substrate, a manufacturing method of the epitaxial substrate and a manufacturing method of a LED apparatus capable of simplifying semiconductor manufacturing steps.

To achieve the above, the present invention discloses a manufacturing method of an epitaxial substrate including the steps of: forming a sacrificial layer, which has a first micro/nano structure, on a substrate, and forming a buffer layer on the sacrificial layer.

In addition, the present invention further discloses a manufacturing method of an epitaxial substrate including the steps of: forming a buffer layer on a substrate; forming a sacrificial layer, which has a first micro/nano structure, on the buffer layer; etching the buffer layer with the sacrificial layer serving as an etching mask so that the buffer layer has a second micro/nano structure corresponding to the first micro/nano structure; and removing the sacrificial layer by etching or calcination.

To achieve the above, the present invention also discloses an epitaxial substrate including a substrate and a buffer layer. The buffer layer is disposed on the substrate and has a micro/nano structure.

Moreover, the present invention also discloses a manufacturing method of a light emitting diode (LED) apparatus including the steps of: providing an epitaxial substrate having a micro/nano structure; forming a first semiconductor layer on the micro/nano structure of the epitaxial substrate; forming an active layer on the first semiconductor layer; and forming a second semiconductor layer on the active layer.

As mentioned above, the epitaxial substrate, the manufacturing method thereof and the manufacturing method of the LED apparatus according to the present invention have the following features. First, the sacrificial layer having the micro/nano structure is disposed on the buffer layer or the substrate. Next, the nano-particles are removed by etching or calcination so that the buffer layer or the substrate has the micro/nano holes. In addition, compared with the prior art, in which the epitaxial substrate is removed by the laser lift-off technology, the epitaxial substrate is removed by etching in the manufacturing method of the LED apparatus of the present invention. Thus, the manufacturing processes can be simplified, and the production yield can be enhanced according to the epitaxial substrate, the manufacturing method thereof and the manufacturing method of the LED apparatus of the present invention.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIGS. 1A to 1G show manufacturing processes of the conventional LED apparatus;

FIG. 2 is a flow chart showing a manufacturing method of an epitaxial substrate according to a first embodiment of the present invention;

FIGS. 3A to 3C show manufacturing processes of the epitaxial substrate according to the first embodiment of the present invention;

FIG. 4 is a flow chart showing a manufacturing method of an epitaxial substrate according to a second embodiment of the present invention;

FIGS. 5A to 5F show manufacturing processes of the epitaxial substrate according to the second embodiment of the present invention;

FIG. 6 is a flow chart showing a manufacturing method of an epitaxial substrate according to a third embodiment of the present invention;

FIGS. 7A to 7F show manufacturing processes of the epitaxial substrate according to the third embodiment of the present invention;

FIG. 8 is a flow chart showing a manufacturing method of a LED apparatus according to a preferred embodiment of the present invention; and

FIGS. 9A to 9E show manufacturing processes of the LED apparatus according to the preferred embodiment of the present invention.

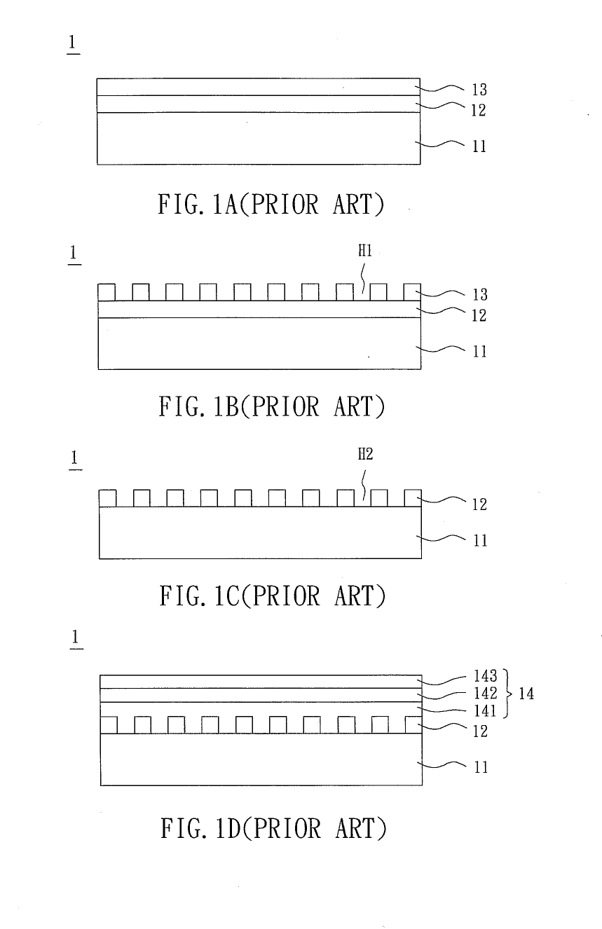

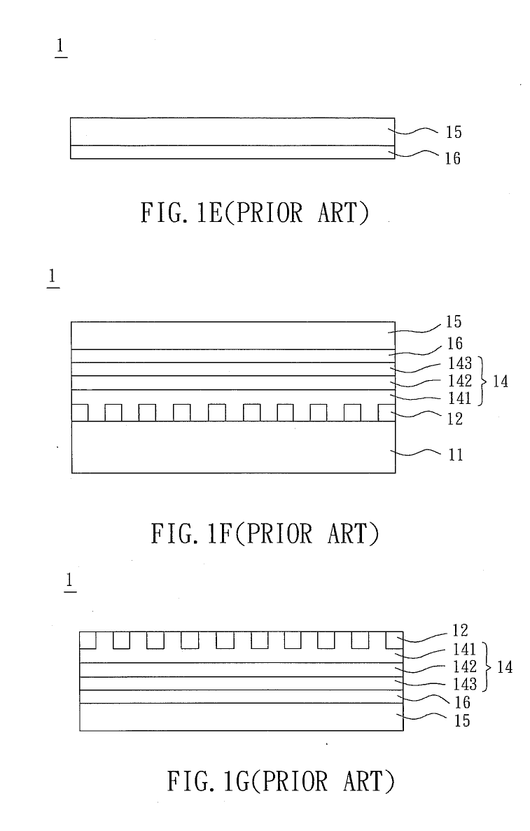

### DETAILED DESCRIPTION OF THE INVENTION

The present invention will be apparent from the following detailed description, which proceeds with reference to the accompanying drawings, wherein the same references relate to the same elements.

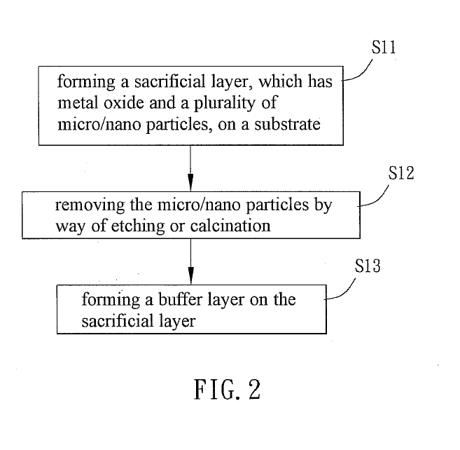

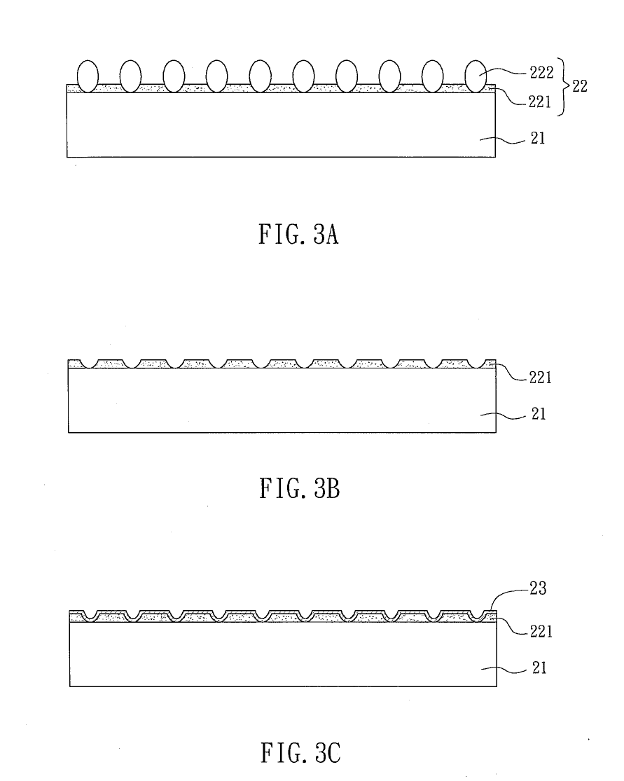

Referring to FIG. 2, a manufacturing method of an epitaxial substrate according to a first embodiment of the present invention includes steps S11 to S13. Illustrations will be made with reference to FIGS. 2 and 3A to 3C.

As shown in FIG. 3A, a sacrificial layer 22 is formed on a substrate 21 in the step S11. In this embodiment, the sacrificial layer 22 is formed by mixing metal oxide 221 and a plurality of micro/nano particles 222 with the properly adjusted ratio so that the micro/nano particles 222 are periodically arranged in the metal oxide 221.

The material of the micro/nano particle 222 includes metal, dielectric material, organic material or inorganic material. The micro/nano particle 222 may be a nano-ball, a nano-column, a nano-hole, a nano-point, a nano-line or a nano-concave-convex structure. Herein, the micro/nano particle 222 is the nano-ball, and the material of the metal oxide 221 includes aluminum oxide.

As shown in FIG. 3B, the micro/nano particle 222 is removed by etching or calcination in the step S12. At this time, the sacrificial layer 22 has a first micro/nano structure. As shown in FIG. 3C, a buffer layer 23 is formed on the sacrificial layer 22 in the step S13. In this embodiment, the buffer layer 23 includes aluminum nitride or gallium nitride.

It is to be noted that the order of the steps can be changed according to the actual requirement of the manufacturing processes.

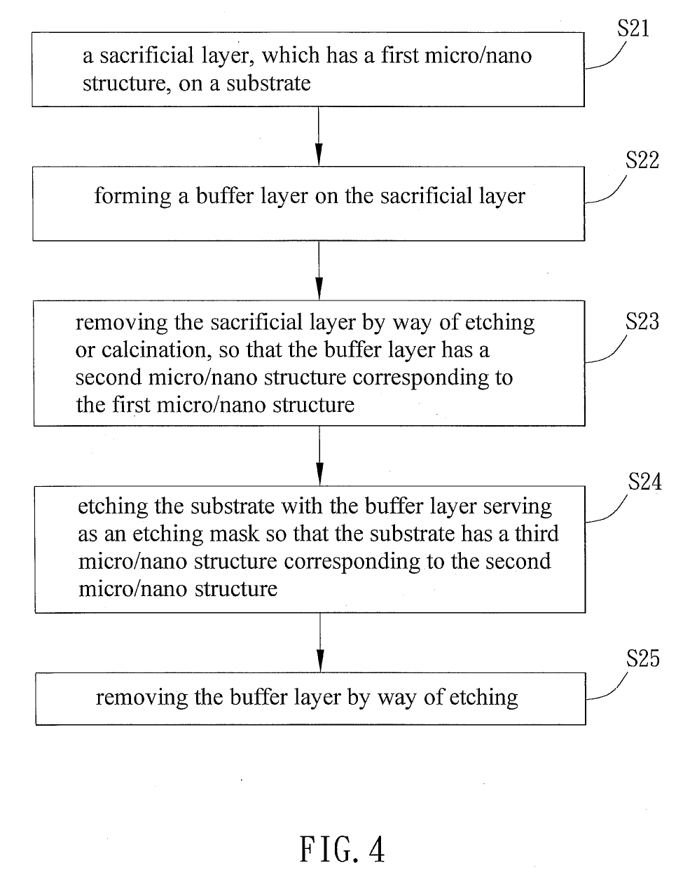

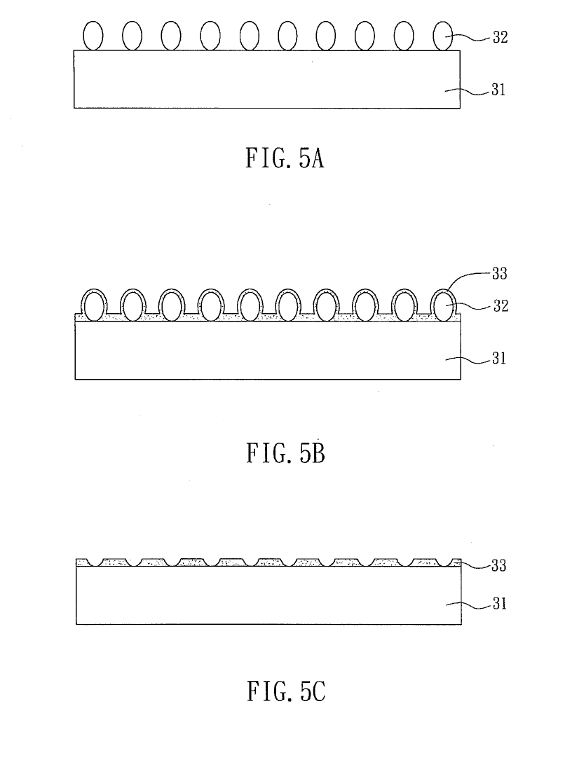

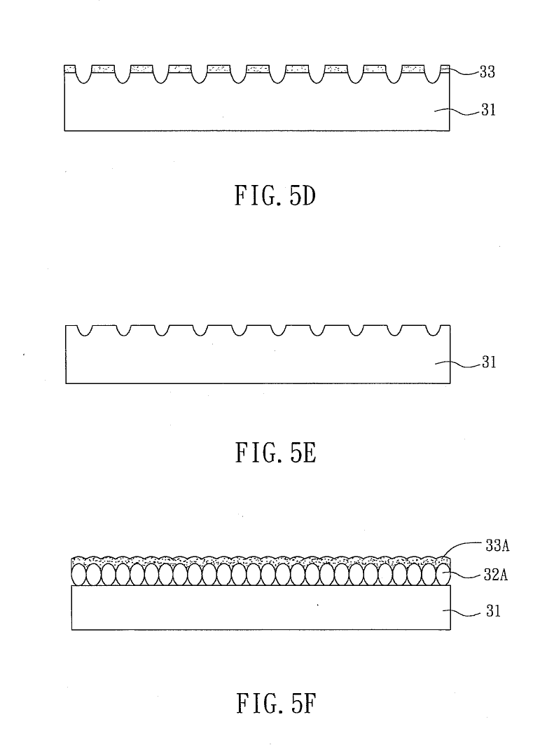

As shown in FIG. 4, a manufacturing method of an epitaxial substrate according to a second embodiment of the present invention includes steps S21 to S25. Illustrations will be made with reference to FIGS. 4 and 5A to 5E.

As shown in FIG. 5A, a sacrificial layer 32 is formed on a substrate 31 in the step S21. Herein, the sacrificial layer 32 has a first micro/nano structure. The first micro/nano structure is formed by stacking, sintering, anode aluminum oxide (AAO) processing, nano-imprinting, transfer printing, hot pressing, etching or electron beam writer (E-beam writer) processing.

In this embodiment, the first micro/nano structure has a plurality of micro/nano particles including at least one nano-ball, nano-column, nano-hole, nano-point, nano-line or nano-concave-convex structure. Herein, the first micro/nano structure is the nano-ball, and the material of the micro/nano particle may include metal, dielectric material, organic material or inorganic material. The micro/nano particles are arranged in a periodic manner, non-periodic manner, continuous manner, non-continuous manner, gap-free manner, gap-containing manner, equally spaced manner or unequally spaced manner.

As shown in FIG. 5B, a buffer layer 33 is formed on the sacrificial layer 32 in the step S22. Herein, the thickness of the buffer layer 33 is smaller than that of the sacrificial layer 32, and the buffer layer 33 includes aluminum nitride or gallium nitride.

As shown in FIG. 5C, the sacrificial layer 32 is removed by etching or calcination in the step S23. Accordingly, the buffer layer 33 has a second micro/nano structure corresponding to the first micro/nano structure.

As shown in FIG. 5D, the substrate 31 is etched with the buffer layer 33 serving as an etching mask in the step S24. Accordingly, the substrate 31 has a third micro/nano structure corresponding to the second micro/nano structure. As shown in FIG. 5E, the buffer layer 33 is removed by etching in the step S25.

In addition, the user can select one of the structures in FIGS. 5C to 5E as the epitaxial substrate according to the actual requirement, and an epitaxy multilayer (to be described in the following) is formed on the epitaxial substrate.

It is to be noted that the order of the above-mentioned steps is not particularly limited and can be changed according to the requirement of the manufacturing processes.

In addition, as shown in FIG. 5F, what is different from the above-mentioned structures is that a sacrificial layer 32A having nano-balls arranged side by side is formed on the substrate 31, and then a buffer layer 33A is formed on the sacrificial layer 32A.

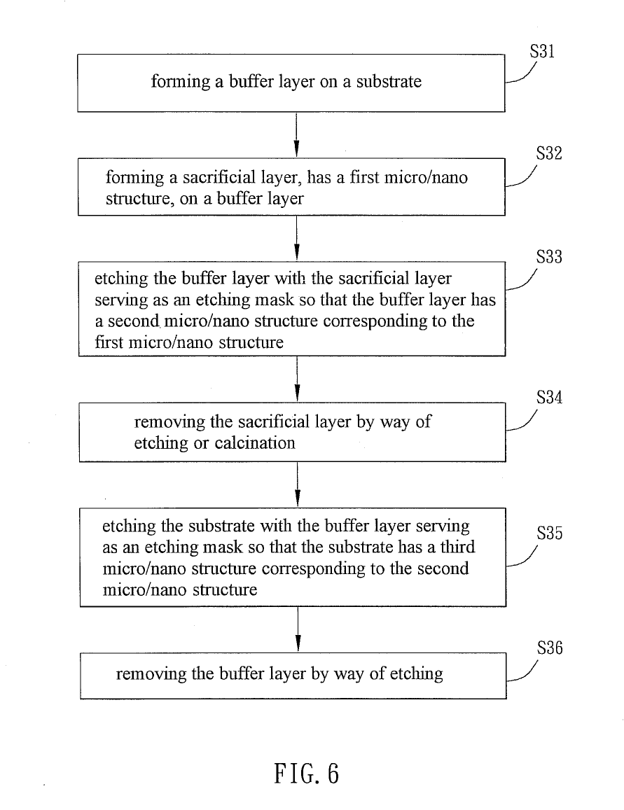

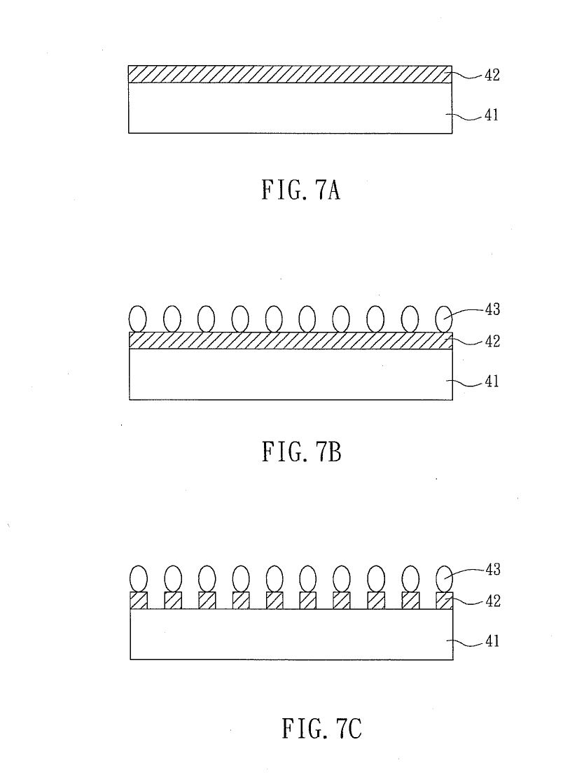

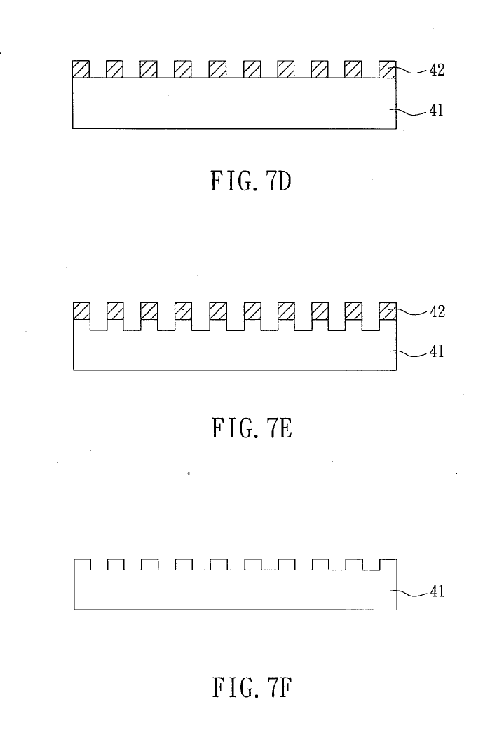

As shown in FIG. 6, a manufacturing method of an epitaxial substrate according to a third embodiment of the present invention includes steps S31 to S36. Illustrations will be made with reference to FIGS. 6 and 7A to 7F.

As shown in FIG. 7A, a buffer layer 42 is formed on a substrate 41 in the step S31. In this embodiment, the material of the buffer layer 42 can be aluminum nitride or gallium nitride.

As shown in FIG. 7B, a sacrificial layer 43 is formed on a buffer layer 43 in the step S32. In this embodiment, the sacrificial layer 43 has a first micro/nano structure, which is manufactured by stacking, sintering, anode aluminum oxide processing, nano-imprinting, transfer printing, hot pressing, etching or electron beam exposure.

Herein, the first micro/nano structure has a plurality of micro/nano particles including at least one nano-ball, a nano-column, a nano-hole, a nano-point, a nano-line or a nano-concave-convex structure. In this embodiment, the first micro/nano structure is the nano-ball, and the material of the micro/nano particle includes metal, dielectric material, organic material or inorganic material.

As shown in FIG. 7C, the buffer layer 42 is etched with the sacrificial layer 43 serving as an etching mask in the step S33. Accordingly, the buffer layer 42 has a second micro/nano structure corresponding to the first micro/nano structure.

As shown in FIG. 7D, the sacrificial layer 43 is removed by etching or calcination in the step S34. As shown in FIG. 7E, the substrate 41 is etched with the buffer layer 42 serving as an etching mask in the step S35 so that the substrate 41 has a third micro/nano structure corresponding to the second micro/nano structure. As shown in FIG. 7F, the buffer layer 42 is removed by etching in the step S36.

In addition, the user can select one of the structures in FIGS. 7D to 7F as the epitaxial substrate according to the actual requirement, and an epitaxy multilayer (to be described in the following) is formed on the epitaxial substrate.

It is to be noted that the order of the steps can be changed according to the actual requirement of the manufacturing processes.

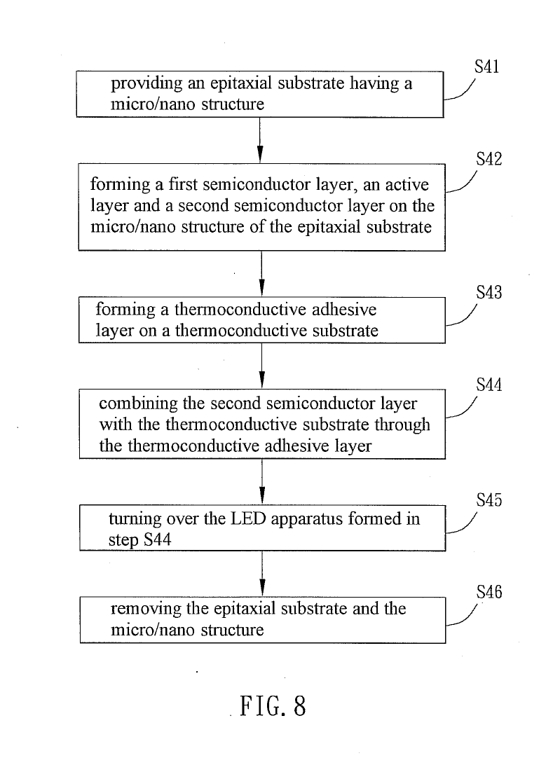

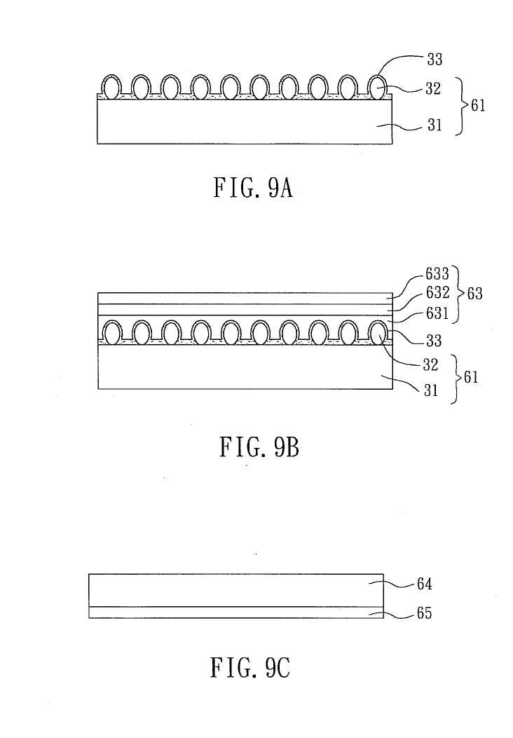

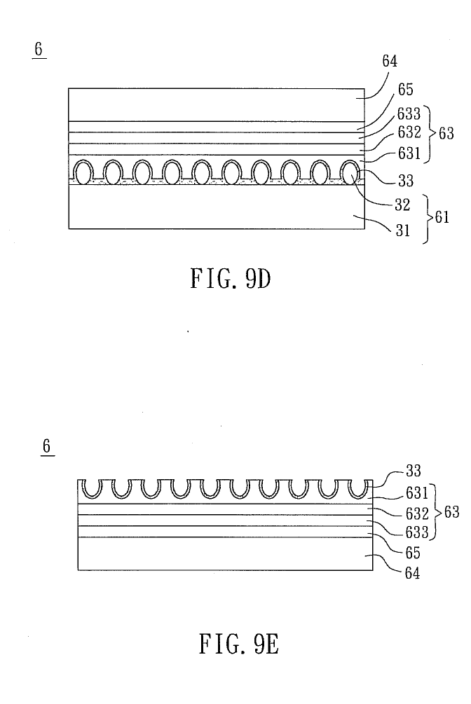

As mentioned hereinabove, the manufacturing method of the LED apparatus of the present invention can be performed based on the epitaxial substrate in the above-mentioned embodiment. As shown in FIG. 8, the manufacturing method includes steps S41 to S46. Illustrations will be made with reference to FIGS. 8 and 9A to 9F.

As shown in FIG. 9A, an epitaxial substrate 61 having a micro/nano structure is provided in the step S41. Herein, the epitaxial substrate 61 is the epitaxial substrate of the second embodiment in FIG. 5B and includes the substrate 31, the sacrificial layer 32 and the buffer layer 33.

Next, as shown in FIG. 9B, an epitaxy multilayer 63 is formed on the buffer layer 33 in the step S42. The epitaxy multilayer 63 includes a first semiconductor layer 631, an active layer 632 and a second semiconductor layer 633 in sequence. In this embodiment, the first semiconductor layer 631 is formed on the buffer layer 33. Next, the first semiconductor layer 631 is formed on the active layer 632, and then the second semiconductor layer 633 is formed on the active layer 632. In addition, the first semiconductor layer 631 and the second semiconductor layer 633 can be an N-type epitaxial layer and a P-type epitaxial layer or can be the P-type epitaxial layer and the N-type epitaxial layer, respectively.

As shown in FIG. 9C, a thermoconductive adhesive layer (also referred to as a bonding layer) 65 is formed on a thermoconductive substrate 64 in the step S43. In this embodiment, the material of the thermoconductive substrate 64 includes silicon, gallium arsenide, gallium phosphide, silicon carbide, boron nitride, aluminum, aluminum nitride, copper or combinations thereof. The material of the thermoconductive adhesive layer 65 can be selected from the group consisting of various metallic or non-metal materials or combinations thereof, such as gold, soldering paste, tin-silver paste or silver paste.

It is to be noted that the thermoconductive adhesive layer 65 can be formed on the thermoconductive substrate 64, the second semiconductor layer 633, or the thermoconductive substrate 64 and the second semiconductor layer 633 simultaneously.

As shown in FIG. 9D, the second semiconductor layer 633 is combined with the thermoconductive substrate 64 through the thermoconductive adhesive layer 65 in the step S44. Finally, as show in FIG. 9E, the LED apparatus 6 formed in the step S44 is turned over in the step S45 and the epitaxial substrate 61 is removed by etching.

It is to be noted that the order of the steps can be changed according to the actual requirement of the manufacturing processes.

Herein, the manufacturing method of the LED apparatus is only described according to the above-mentioned examples, wherein the epitaxial substrate used in the manufacturing processes is, for example but not limited to, any one of the epitaxial substrates according to the first to third embodiments, or other epitaxial substrates manufacturing according to the concept of the present invention.

In summary, the epitaxial substrate, the manufacturing method thereof and the manufacturing method of the LED apparatus according to the present invention have the following features. First, the sacrificial layer having the micro/nano structure is disposed on the buffer layer or the substrate. Next, the nano-particles are etched by etching or calcination so that the buffer layer or the substrate has the micro/nano holes. In addition, compared with the prior art, in which the epitaxial substrate is removed by the laser lift-off technology, the epitaxial substrate is removed by etching in the manufacturing method of the LED apparatus of the present invention. Thus, the manufacturing processes can be simplified, and the production yield can be enhanced according to the epitaxial substrate, the manufacturing method thereof and the manufacturing method of the LED apparatus of the invention.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A manufacturing method of an epitaxial substrate, comprising steps of:
forming a sacrificial layer on a substrate; and
forming a buffer layer on the sacrificial layer,
wherein the sacrificial layer comprises a first micro/nano structure.

2. The manufacturing method according to claim 1, wherein the sacrificial layer comprises a plurality of micro/nano particles, and the first micro/nano structure is formed after the plurality of micro/nano particles are removed.

3. The manufacturing method according to claim 2, wherein the plurality of micro/nano particles are arranged with any gap formed therebetween, or arranged side by side.

4. The manufacturing method according to claim 2, wherein the plurality of micro/nano particles comprises metal, dielectric material, organic material or inorganic material, and the sacrificial layer comprises the micro/nano particles and metal oxide.

5. The manufacturing method according to claim 2, wherein the plurality of micro/nano particles are removed by etching or calcination.

6. The manufacturing method according to claim 1, wherein a thickness of the buffer layer is smaller than that of the sacrificial layer.

7. The manufacturing method according to claim 1, wherein the buffer layer comprises a second micro/nano structure formed on the sacrificial layer by stacking, sintering, anodic aluminum oxidizing (AAO), nano-imprinting, transfer printing, hot pressing, etching or electron beam writer (E-beam writer) processing.

8. The manufacturing method according to claim 1, wherein the first micro/nano structure comprises a nano-ball, nano-column, nano-hole, nano-point, nano-line or nano-concave-convex structure formed by stacking, sintering, anodic aluminum oxidizing, nano-imprinting, transfer printing, hot pressing, etching or electron beam writer processing.

9. The manufacturing method according to claim 1, further comprising a step of forming an epitaxial layer at one side of the buffer layer.

10. The manufacturing method according to claim 9, wherein the epitaxial layer comprises a first semiconductor layer, an active layer and a second semiconductor layer.

11. The manufacturing method according to claim 9, further comprising a step of forming a thermally conductive substrate and an adhesive layer at one side of the epitaxial layer.

12. The manufacturing method according to claim 11, further comprising a step of removing the sacrificial layer and a portion of the buffer layer.

13. A manufacturing method of an epitaxial substrate, comprising steps of:
forming a buffer layer on a substrate, wherein the buffer layer comprises a first micro/nano structure; and
etching the substrate by using the buffer layer as an etching mask to form a second micro/nano structure on the substrate.

14. The manufacturing method according to claim 13, wherein the first micro/nano structure is formed by forming a plurality of micro/nano particles on the substrate before forming the buffer layer, and removing the micro/nano particles after forming the buffer layer to form the first micro/nano structure.

15. The manufacturing method according to claim 13, wherein the plurality of micro/nano particles comprise metal, dielectric material, organic material or inorganic material.

16. The manufacturing method according to claim 13, wherein the first micro/nano structure comprises a nano-ball, nano-column, nano-hole, nano-point, nano-line or nano-concave-convex structure formed by stacking, sintering, anodic aluminum oxidizing, nano-imprinting, transfer printing, hot pressing, etching or electron beam writer processing.

17. The manufacturing method according to claim 13, further comprising a step of forming a sacrificial layer on the buffer layer, wherein the sacrificial layer comprises a plurality of micro/nano particles.

18. The manufacturing method according to claim 17, further comprising a step of etching the buffer layer by using the plurality of micro/nano particles as an etching mask to form the first micro/nano structure.

19. A light emitting diode apparatus comprising:
a substrate; and
a buffer layer disposed on the substrate and having a micro/nano structure.

20. The light emitting diode apparatus according to claim 19, wherein the buffer layer and the substrate are integrally formed as a single unit.

21. The light emitting diode apparatus according to claim 19, wherein a material of the buffer layer comprises aluminum nitride or gallium nitride.

22. The light emitting diode apparatus according to claim 19, wherein the micro/nano structure is formed by way of stacking, sintering, anodic aluminum oxidizing (AAO), nano-imprinting, transfer printing, hot pressing, etching or electron beam writer (E-beam writer) processing.

23. The light emitting diode apparatus according to claim 19, wherein the micro/nano structure comprises a nano-ball, a nano-column, a nano-hole, a nano-point, a nano-line or a nano-concave-convex structure.

24. The light emitting diode apparatus according to claim 19, further comprising a sacrificial layer disposed between the substrate and the buffer layer.

25. The light emitting diode apparatus according to claim 19, further comprising:
a first semiconductor layer disposed on the micro/nano structure;
an active layer on the first semiconductor layer;
a second semiconductor layer disposed on the active layer;
a thermoconductive substrate; and
a thermoconductive adhesive layer disposed between the second semiconductor layer and the thermoconductive substrate.
